(19) United States
(12) Patent Application Publication
(10) Pub. No.: US 2025/0380555 A1
(43) Pub. Date: Dec. 11, 2025

(54) PACKAGING STRUCTURE AND METHOD FOR PACKAGING

(71) Applicant: INDUSTRIAL TECHNOLOGY RESEARCH INSTITUTE, Hsinchu (TW)

(72) Inventors: Chun-Chen CHIANG, Hsinchu City (TW); Chyi-Ming LEU, Jhudong Township (TW); Kuan-Wei CHEN, Zhudong Township (TW); Xin-Yu ZENG, Zhudong Township (TW)

(73) Assignee: INDUSTRIAL TECHNOLOGY RESEARCH INSTITUTE, Hsinchu (TW)

(21) Appl. No.: 19/221,938

(22) Filed: May 29, 2025

Related U.S. Application Data
(63) Continuation-in-part of application No. 19/028,098, filed on Jan. 17, 2025.

(30) Foreign Application Priority Data
May 30, 2024 (TW) 113119999

(51) Int. Cl. H10H 29/854; H10H 29/01; H10H 29/24; H10H 29/853

(52) U.S. Cl. CPC H10H 29/854; H10H 29/0362; H10H 29/24; H10H 29/853

(57) ABSTRACT

A packaging structure and method for packaging are provided. The packaging structure includes a substrate, a plurality of light-emitting elements, and a composite film. The light-emitting elements are disposed on the substrate, and the composite film is disposed on the substrate, covering the light-emitting elements. The composite film includes a first layer and a second layer. The first layer includes a first thermoplastic material, wherein the melt flow rate (MFR) of the first thermoplastic material is R1, and the first thermoplastic material is an ethylene-propylene copolymer, polyethylene terephthalate, or a combination thereof. The second layer includes a second thermoplastic material, wherein the melt flow rate (MFR) of the second thermoplastic material is R2, and −11≤(R1−R2)≤11. The second thermoplastic material is a styrene-ethylene-butylene-styrene block copolymer, an ethylene-vinyl acetate copolymer (EVA), or a combination thereof.

### CROSS REFERENCE TO RELATED APPLICATIONS

This application is a continuation-in-part application of U.S. patent application Ser. No. 19/028,098, filed on Jan. 17, 2025, which claims the priority of Taiwan Patent Application No. 113119999, filed on May 30, 2024, the entirety of which are incorporated by reference herein.

### TECHNICAL FIELD

The disclosure is related to a packaging structure and a method for packaging.

### BACKGROUND

Small to medium-sized backlight modules are gradually being replaced by sub-millimeter light-emitting diode (Mini LED) direct backlight modules. The Mini LED array distribution in LED units not only features a large number of LED chips in a compact arrangement, but it also reduces the light-mixing distance, achieving a thinner display. Simultaneously, it enables local dimming to achieve a higher dynamic range. Encapsulation materials are fully applied over the LED units to protect the thousands of LEDs on the surface. Conventional encapsulation materials include silicone, epoxy resin, and optical clear adhesive (OCA).

However, it is a struggle to balance the requirements of transmittance and haze using conventional encapsulation materials.

Therefore, there is an urgent need to develop new encapsulation materials that can provide a balance between transmittance and haze.

### SUMMARY

According to embodiments of the disclosure, the disclosure provides a packaging structure. According to embodiments of the disclosure, the packaging structure (which may be a packaging structure for a backlight module used in a display device) may include a substrate, a plurality of light-emitting elements, and a composite film. According to embodiments of the disclosure, the light-emitting elements may be disposed on the substrate, and the composite film may be disposed on the substrate to cover the light-emitting elements. The composite film includes a first layer and a second layer. The first layer includes a first thermoplastic material, wherein the melt flow rate (MFR) of the first thermoplastic material is R1, wherein the first thermoplastic material is an ethylene-propylene copolymer, polyethylene terephthalate (PET), or a combination thereof. The second layer includes a second thermoplastic material, wherein the melt flow rate (MFR) of the second thermoplastic material is R2, and −11≤(R1−R2)≤11, wherein the second thermoplastic material is a styrene-ethylene-butylene-styrene block copolymer (SEBS), an ethylene-vinyl acetate copolymer (EVA), or a combination thereof.

According to embodiments of the disclosure, the second layer of the composite film contacts the light-emitting elements.

According to embodiments of the disclosure, the disclosure provides a method for packaging. According to embodiments of the disclosure, the method for packaging includes providing a substrate, wherein a plurality of light-emitting elements is disposed on the substrate; providing the composite film of the disclosure; and disposing the composite film on the substrate via a thermocompression process to cover the light-emitting elements.

A detailed description is given in the following embodiments.

### BRIEF DESCRIPTION OF THE DRAWINGS

The present disclosure can be more fully understood by reading the subsequent detailed description and examples with references made to the accompanying drawings, wherein:

FIG. 1 is a schematic view of a packaging structure according to embodiments of the disclosure.

FIG. 2 is a schematic view of a packaging structure according to other embodiments of the disclosure.

FIG. 3 is a flow chart illustrating a method for packaging according to embodiments of the disclosure.

### DETAILED DESCRIPTION

The packaging structure and method for packaging of the disclosure are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. As used herein, the term “about” in quantitative terms refers to plus or minus an amount that is general and reasonable to persons skilled in the art.

Further, the use of ordinal terms such as “first”, “second”, “third”, etc., in the disclosure to modify an element does not by itself connote any priority, precedence, order of one claim element over another or the temporal order in which it is formed, but are used merely as labels to distinguish one claim element having a certain name from another element having the same name (but for use of the ordinal term) to distinguish the claim elements.

The drawings described are only schematic and are non-limiting. In the drawings, the size, shape, or thickness of some of the elements may be exaggerated and not drawn on scale for illustrative purposes. The dimensions and the relative dimensions do not correspond to actual location to practice of the disclosure. The disclosure will be described with respect to particular embodiments and with reference to certain drawings but the disclosure is not limited thereto.

It should be noted that the elements or devices in the drawings of the disclosure may be present in any form or configuration known to those skilled in the art. In addition, the expression “a layer overlying another layer”, “a layer is disposed above another layer”, “a layer is disposed on another layer”, and “a layer is disposed over another layer” may refer to a layer that directly contacts the other layer, and they may also refer to a layer that does not directly contact the other layer, there being one or more intermediate layers disposed between the layer and the other layer.

The disclosure provides a packaging structure and method for packaging, such as a packaging structure for a backlight module used in a display device (e.g. Mini LED backlight module) and a method for packaging. The packaging structure of the disclosure may include a substrate, a plurality of light-emitting elements, and a composite film. In some embodiments, the composite film may comprise a first layer and a second layer, and has high transmittance (such as transmittance greater than or equal to 80%), high haze (such as haze greater than or equal to 60%), high stability, and high adhesion (the adhesion between the composite film and the substrate may be of 800 gf/25 mm to 2500 gf/25 mm). Therefore, the composite film of the disclosure is suitable for use as an encapsulation material to be applied in the packaging structure (such as being disposed on a substrate with electronic components). In some embodiments, the composite film of the packaging structure can be removed through a debonding process without damaging the electronic components on the substrate. As a result, the reworkability of the packaging structure and product yield can be improved. In some embodiments, the first layer of the composite film includes a first thermoplastic material (such as an ethylene-propylene copolymer thermoplastic elastomer), and the second layer of the composite film includes a second thermoplastic material (such as a styrene-ethylene-butylene-styrene block copolymer, or an ethylene-vinyl acetate copolymer (EVA) thermoplastic elastomer). The composite film may be prepared through a co-extrusion process, thereby simplifying the process and reducing production costs.

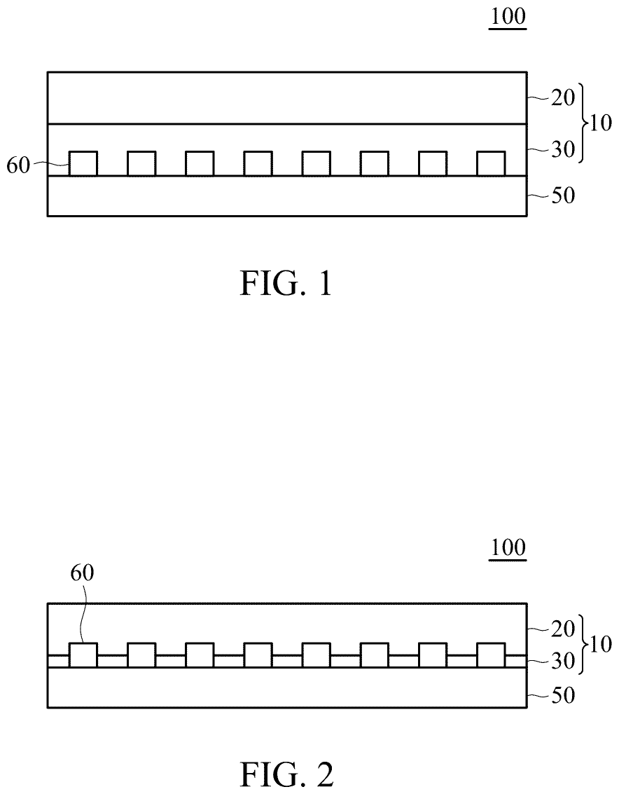

According to embodiments of the disclosure, As shown in FIG. 1, the packaging structure of the disclosure 100 includes a substrate 50, a plurality of light-emitting elements 60, and the composite film 10. The light-emitting elements 60 are disposed on the substrate 50, and the composite film 10 is disposed on the substrate 50 to cover the light-emitting elements 60.

According to embodiments of the disclosure, the composite film 10 may be a double-layered structure including a first layer 20 and a second layer 30. According to embodiments of the disclosure, the second layer 30 of the composite film 10 may contact the light-emitting elements 60, and the first layer 20 of the composite film 10 does not contact the light-emitting elements 60, as shown in FIG. 1. Namely, the first layer 20 and the light-emitting elements 60 are separated by the second layer 30. In addition, each of the light-emitting elements 60 has a bottom surface, a top surface and a side surface, wherein the bottom surface of the light-emitting elements 60 may contact the substrate, and the top surface and the side surface of the light-emitting elements 60 are covered by the second layer 30.

According to some embodiments of the disclosure, the first layer 20 and the second layer 30 of the composite film 10 can both be in contact with the light-emitting elements 60, as shown in FIG. 2. Namely, the light-emitting element 60 has a bottom surface, a top surface and a side surface, wherein the bottom surface of the light-emitting elements 60 contacts the substrate, the side surface of the light-emitting elements 60 is covered by the first layer 20 and second layer 30, and the top surface of the light-emitting elements 60 is covered by the first layer 20.

According to embodiments of the disclosure, the composite film 10 may comprise the first layer 20 and the second layer 30. According to embodiments of the disclosure, the thickness of the first layer 20 and the thickness of the second layer 30 may be independently about 10 μm to 1,000 μm (such as about 15 μm, 20 μm, 30 μm, 50 μm, 100 μm, 200 μm, 300 μm, 400 μm, 500 μm, 600 μm, 700 μm, 800 μm, or 900 μm). According to embodiments of the disclosure, the thickness ratio of the first layer 20 to the second layer 30 may be about 1:10 to 10:1 (such as about 1:9, 1:8, 1:7, 1:6, 1:5, 1:4, 1:3, 1:2, 1:1, 2:1, 3:1, 4:1, 5:1, 6:1, 7:1, 8:1, or 9:1).

According to embodiments of the disclosure, the substrate 50 may be, for example, a substrate for a light diode backlight module. According to embodiments of the disclosure, the substrate 50 may be a glass substrate, plastic substrate, or semiconductor substrate. According to embodiments of the disclosure, the light-emitting element 60 may be a diode light-emitting element.

According to embodiments of the disclosure, the first layer 20 of the composite film 10 may include a first thermoplastic material, wherein the first thermoplastic material may be an ethylene-propylene copolymer, polyethylene terephthalate, or a combination thereof. Herein, the melt flow rate (MFR) of the first thermoplastic material is R1, wherein R1 may be about 0.1 g/10 min to 70 g/10 min (such as about 1 g/10 min, 5 g/10 min, 10 g/10 min, 15 g/10 min, 20 g/10 min, 25 g/10 min, 30 g/10 min, 35 g/10 min, 40 g/10 min, 45 g/10 min, 50 g/10 min, 55 g/10 min, 60 g/10 min, or 65 g/10 min). According to embodiments of the disclosure, the molecular weight of the first thermoplastic material can be varied to obtain a melt flow rate (MFR) of the first thermoplastic material within a range of about 0.1 g/10 min to 70 g/10 min. Herein, the melt flow rate (MFR) of the thermoplastic material may be determined via a melt flow indexer at 230° C. with a test weight of 2.16 kg, measured according to the method specified in ASTM D 1238-A. According to some embodiments of the disclosure, the first layer 20 of the composite film 10 may consist of the first thermoplastic material.

According to embodiments of the disclosure, the ethylene-propylene copolymer (serving as the first thermoplastic material) may be an ethylene-propylene block copolymer. Namely, the ethylene-propylene copolymer may include a polyethylene (PE) block (prepared by polymerizing ethylene monomer) and a polypropylene (PP) block (prepared by polymerizing propylene monomer), wherein the content of the polyethylene (PE) block may be about 7 wt % to 15 wt % (such as about 8 wt %, 9 wt %, 10 wt %, 11 wt %, 12 wt %, 13 wt %, or 14 wt %), based on the weight of the polypropylene (PP) block of the ethylene-propylene copolymer. According to embodiments of the disclosure, the ethylene-propylene copolymer may be a thermoplastic elastomer. When the content of the polyethylene (PE) block of the ethylene-propylene copolymer is less than 7 wt %, the obtained composite film has poor haze, which limits the enhancement of luminous uniformity of the obtained packaging structure. When the content of the polyethylene (PE) block of the ethylene-propylene copolymer is greater than 15 wt %, the transmittance of the obtained composite film is reduced, thereby leading to poorer transmittance in the obtained packaging structure. According to the embodiments of the disclosure, the ethylene-propylene copolymer may consist of polyethylene blocks and polypropylene blocks. Further, when a propylene homopolymer is used instead of an ethylene-propylene copolymer as the first thermoplastic material of the disclosure, the obtained composite film exhibits poorer impact resistance, dimensional stability, and thermal stability.

According to embodiments of the disclosure, the first layer 20 of the composite film 10, in addition to the first thermoplastic material, may further include a first diffusion particle (not shown) to increase the haze of the composite film. According to embodiments of the disclosure, the first diffusion particle may be silicon dioxide, poly(methyl methacrylate) (PMMA), polystyrene, titanium oxide, or a combination thereof. According to embodiments of the disclosure, the particle size distribution D90 of the first diffusion particle may be about 10 nm to 10 μm (such as about 20 nm, 30 nm, 50 nm, 100 nm, 200 nm, 300 nm, 500 nm, 1 μm, 2 μm, 3 μm, 4 μm, 5 μm, 6 μm, 7 μm, 8 μm, or 9 μm). Herein, the particle size distribution D90 means that 90 vol % of the total particles have a diameter less than the value defined by D90. According to embodiments of the disclosure, the particle size distribution D90 is measured according to the standard ISO 13322−1:2014.

According to embodiments of the disclosure, when the first layer 20 of the composite film 10 includes the first thermoplastic material and the first diffusion particle, the amount of the first diffusion particle may be about 0.1 wt % to 30 wt % (such as about 0.2 wt %, 0.5 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, or 29 wt %), based on the total weight of the first thermoplastic material and the first diffusion particle. When the content of the first diffusion particle is too high, the obtained composite film exhibits poorer weather resistance, leading to decreased stability of the obtained packaging structure, and the composite film is prone to cracking when removed after the debonding process. According to embodiments of the disclosure, the first layer 20 of the composite film 10 may consist of the first thermoplastic material and the first diffusion particle. According to embodiments of the disclosure, the first layer 20 of the composite film 10 may consist of the first thermoplastic material, or the first layer 20 includes the first thermoplastic material and the first diffusion particle.

According to embodiments of the disclosure, the first layer 20 of the composite film 10, in addition to the first thermoplastic material and the first diffusion particle, may further include a second diffusion particle (not shown) to increase the haze of the composite film, wherein the particle size distribution D90 of the second diffusion particle is less than the particle size distribution D90 of the first diffusion particle. According to embodiments of the disclosure, the second diffusion particle may be silicon dioxide, poly(methyl methacrylate) (PMMA), polystyrene, titanium oxide, or a combination thereof. According to embodiments of the disclosure, the particle size distribution D90 of the second diffusion particle may be about 10 nm to 5 μm, 10 nm to 4 μm, 10 nm to 3 μm, 10 nm to 2 μm, 50 nm to 2 μm, or 100 nm to 2 μm (such as about 20 nm, 30 nm, 50 nm, 100 nm, 200 nm, 300 nm, 500 nm, 1 μm, 2 μm, 3 μm, or 4 μm). According to embodiments of the disclosure, when the first layer 20 of the composite film 10 includes the first thermoplastic material, the first diffusion particle, and the second diffusion particle, the amount of the first diffusion particle may be about 0.1 wt % to 30 wt % (such as about 0.2 wt %, 0.5 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, or 29 wt %), and the amount of the second diffusion particle may be about 0.01 wt % to 0.15 wt % (such as about 0.02 wt %, 0.05 wt %, or 0.1 wt %), based on the total weight of the first thermoplastic material, the first diffusion particle, and the second diffusion particle. According to embodiments of the disclosure, the first layer 20 of the composite film 10 may consist of the first thermoplastic material, the first diffusion particle, and the second diffusion particle. According to embodiments of the disclosure, the ratio of the particle size distribution D90 of the first diffusion particle to the particle size distribution D90 of the second diffusion particle may be about 2:1 to 200:1, 2:1 to 100:1, 2:1 to 70:1, 2:1 to 50:1, 2:1 to 30:1, 2:1 to 20:1, or 2:1 to 10:1 (such as about 3:1, 4:1, 5:1, 6:1, 7:1, 8:1, 9:1, 10:1).

According to embodiments of the disclosure, the first layer 20 of the composite film 10 has a top surface, wherein a surface microstructure (not shown) may be configured on the top surface of the first layer 20 to enhance the luminous uniformity of the packaging structure. According to embodiments of the disclosure, the surface microstructure may include a pyramidal structure, a sinusoidal structure, or a semi-spherical-like structure, with a depth-to-width ratio of the surface microstructure of about 0.04 to 0.2.

According to embodiments of the disclosure, the second layer 30 of the composite film 10 may include a second thermoplastic material, wherein the second thermoplastic material may be a styrene-ethylene-butylene-styrene block copolymer, an ethylene-vinyl acetate copolymer (EVA), or a combination thereof. Herein, the melt flow rate (MFR) of the second thermoplastic material is R2, wherein R2 may be about 0.1 g/10 min to 70 g/10 min (such as 1 g/10 min, 5 g/10 min, 10 g/10 min, 15 g/10 min, 20 g/10 min, 25 g/10 min, 30 g/10 min, 35 g/10 min, 40 g/10 min, 45 g/10 min, 50 g/10 min, 55 g/10 min, 60 g/10 min, or 65 g/10 min). According to embodiments of the disclosure, the molecular weight of the second thermoplastic material can be varied to obtain a melt flow rate (MFR) of the second thermoplastic material within a range of about 0.1 g/10 min to 70 g/10 min.

According to embodiments of the disclosure, the styrene-ethylene-butylene-styrene block copolymer includes a polystyrene block (prepared by polymerizing styrene monomer) and poly-conjugated-diene (such as polybutene) block (prepared by polymerizing conjugated diene monomer (such as butene)). According to embodiments of the disclosure, the content of the polystyrene block is not limited and may be optionally modified by a person of ordinary skill in the field, such as about 10 wt % to 50 wt %, based on the weight of the styrene-ethylene-butylene-styrene block copolymer. According to embodiments of the disclosure, the ethylene-vinyl acetate copolymer is prepared by copolymerizing ethylene monomer and vinyl acetate (VA) monomer. According to embodiments of the disclosure, the amount of the vinyl acetate (VA) monomer is not limited and may be optionally modified by a person of ordinary skill in the field, such as about 15 wt % to 50 wt %, based on the weight of ethylene-vinyl acetate copolymer (EVA). According to embodiments of the disclosure, the second thermoplastic material (i.e. styrene-ethylene-butylene-styrene block copolymer or ethylene-vinyl acetate copolymer (EVA)) may be a thermoplastic elastomer.

According to embodiments of the disclosure, in addition to the second thermoplastic material, the second layer 30 of the composite film 10 may further include a binder (not shown) in order to increase the adhesion between the composite film and the substrate. According to embodiments of the disclosure, the binder may include aliphatic homopolymer resin, dicyclopentadiene homopolymer resin, aromatic homopolymer resin, or a combination thereof. According to embodiments of the disclosure, the weight ratio of the binder to the second thermoplastic material may be about 1:100 to 3:5 (such as about 2:100, 3:100, 4:100, 5:100, 7:100, 1:10, 1:7, 1:5, 1:4, 1:3, or 1:2). When the binder content is too high, the obtained composite film cannot be completely removed from the packaging substrate after the debonding process, resulting in residual adhesive.

According to embodiments of the disclosure, the second layer 30 of the composite film 10 may consist of the second thermoplastic material and the binder. According to embodiments of the disclosure, the second layer 30 of the composite film 10 may consist of the second thermoplastic material, or the second layer 30 includes the second thermoplastic material and the binder.

According to embodiments of the disclosure, the melt flow rate (MFR) of the first thermoplastic material (R1) used in the first layer and the melt flow rate (MFR) of the second thermoplastic material (R2) used in the second layer conform to the following equation: −11≤(R1−R2)≤11.

According to embodiments of the disclosure, when the melt flow rate (R1) of the first thermoplastic material and the melt flow rate (R2) of the second thermoplastic material conform to the above equation, the composite film of the disclosure can be prepared by a co-extrusion process. The co-extrusion process of the disclosure may include the following steps. First, a first layer material and a second layer material are provided, wherein the first layer material includes the first thermoplastic material, and the second layer material includes the second thermoplastic material. The melt flow rate (R1) of the first thermoplastic material and the melt flow rate (R2) of the second thermoplastic material conform to the above equation. Next, the first layer material and the second layer material are individually added into a twin-screw extruder at a temperature between 190° C. and 230° C. and a screw speed between 250 rpm and 300 rpm to undergo high-temperature melting. The resulting molten materials are introduced into a dual-layer co-extrusion die with an internal flow channel design and then extruded. After cooling and winding the film is collected, and a composite film with a double-layer structure is formed.

According to embodiments of the disclosure, when the difference (R1−R2) between the melt flow rate (R1) of the first thermoplastic material and the melt flow rate (R2) of the second thermoplastic material is less than −11 or greater than 11, it is not possible to continuously form a composite film with a double-layer structure via the co-extrusion process. Herein, the first layer of the composite film includes the first thermoplastic material, which is an ethylene-propylene copolymer, polyethylene terephthalate, or a combination thereof, and the amount of the first thermoplastic material is greater than 50 wt %, based on the weight of the first layer. The second layer of the composite film includes the second thermoplastic material, which is styrene-ethylene-butylene-styrene block copolymer, ethylene-vinyl acetate copolymer, or a combination thereof, and the amount of the second thermoplastic material is greater than 50 wt %, based on the weight of the second layer.

According to embodiments of the disclosure, the composite film of the disclosure has a high haze. For example, the haze of the composite film of the disclosure may be greater than or equal to 60% (such as 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, or 99%).

According to embodiments of the disclosure, the light transmittance and haze are determined by a haze meter (NDH-2000, Nippon Denshoku) according to the method specified in ASTM D1003.

According to embodiments of the disclosure, in the packaging structure, the adhesion between the composite film and the substrate may be about 800 gf/25 mm to 2500 gf/25 mm, such as 900 gf/25 mm, 1000 gf/25 mm, 1200 gf/25 mm, 1500 gf/25 mm, 1700 gf/25 mm, 2000 gf/25 mm, 2200 gf/25 mm, 2300 gf/25 mm, or 2400 gf/25 mm. The adhesion test is conducted using a tensile testing machine (QC-513A2, COMETECH TESTING MACHINES CO., LTD.). The test conditions involve stretching the adhesive and substrate at 180° at room temperature and measuring the peel adhesion between the adhesive (25 mm width) and substrate. The evaluation is performed according to the method specified in ASTM D3330.

According to embodiments of the disclosure, in the packaging structure, the luminous uniformity of the composite film may be even achieved about 40% to 99% (such as about 45%, 50%, 55%, 60%, 65%, 70%, 75%, 80%, 85%, 90%, or 95%). The luminous uniformity test is conducted using a luminance meter (PR-655, TITAN Electro-Optics Co., LTD.). The test is performed at room temperature to determine the luminous uniformity value (U) below the module, wherein U=(I_{dark}/I_{brightness})×100%.

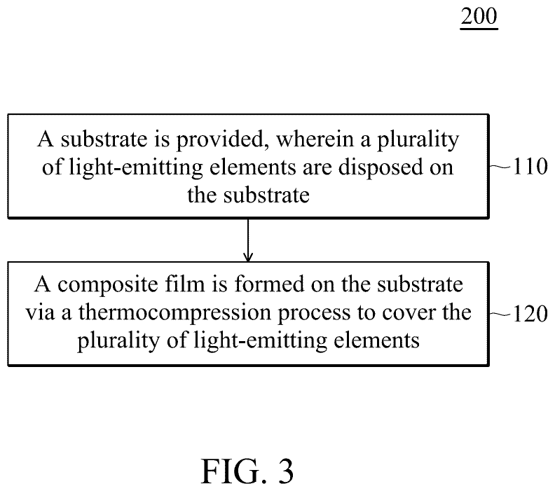

According to embodiments of the disclosure, the disclosure also provides a method for packaging. FIG. 3 is a flow chart illustrating a method for packaging according to embodiments of the disclosure. The method for packaging 200 may include following steps. First, a substrate, with a plurality of light-emitting elements disposed on it, is provided (step 110). Next, a composite film is formed on the substrate via a thermocompression process to cover the light-emitting elements (step 120). Herein, the composite film is the composite film of the disclosure. According to embodiments of the disclosure, the thermocompression process can be performed using a compression molding machine, wherein the thermocompression process may be conducted under vacuum. The molding temperature may range from 130° C. to 150° C., and the thermocompression period may range from 1 minute to 60 minutes. Since the composite film of the disclosure is laminated with the substrate via the second layer (i.e., the film layer containing the second thermoplastic material), and the second thermoplastic material used in the disclosure is a styrene-ethylene-butylene-styrene block copolymer, ethylene-vinyl acetate copolymer, or a combination thereof, the thermocompression molding temperature can be lowered. This prevents damage of the electronic components (i.e., light-emitting elements) on the substrate due to high molding temperatures during the thermocompression process.

According to embodiments of the disclosure, the packaging structure of the disclosure can use a relatively low-temperature heating method to debond the composite film of the packaging structure. This allows the heated composite film to be easily removed from the packaging substrate without pulling up the light-emitting element on the packaging substrate. As a result, the reworkability and product yield of the packaging structure can be improved. The debonding process of the disclosure may include heating the composite film with a hot air gun (with a heating temperature ranging from 100° C. to 120° C. and a heating period of about 1 to 60 minutes).

Below, exemplary embodiments will be described in detail with reference to the accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### Preparation of Composite Film

### Preparation Example 1

A material of the first layer was provided, wherein the material of the first layer was ethylene-propylene copolymer (commercially available from Formosa Plastics Corporation with a trade name of 3600N) (the amount of the ethylene monomer was about 10 wt %, based on the weight of the propylene monomer) (serving as first thermoplastic material with a melt flow rate (R1) of 55 g/10 min). A material for the second layer was provided, wherein the material of the second layer was styrene-ethylene-butylene-styrene block copolymer (SEBS) (commercially available from Wewill Inc. with a trade name of MD6951) (styrene/SEBS was 34 wt %) (serving as second thermoplastic material with a melt flow rate (R2) of 45 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (1) with a double-layer structure was obtained.

Next, the transmittance (%) and haze (%) of Composite film (1) were measured, and the results are shown in Table 1. The transmittance (%) and haze (%) are determined by a haze meter (NDH-2000, Nippon Denshoku) according to the method specified in ASTM D1003.

### Preparation Example 2

A material of the first layer was provided, wherein the material of the first layer was ethylene-propylene copolymer (commercially available from Formosa Plastics Corporation with a trade name of RP3015) (the amount of the ethylene monomer was about 10 wt %, based on the weight of the propylene monomer) (serving as first thermoplastic material with a melt flow rate (R1) of 2 g/10 min). A material of the second layer was provided, wherein the material of the second layer was styrene-ethylene-butylene-styrene block copolymer (SEBS) (commercially available from Asahi KASEI with a trade name of H1502, styrene/SEBS was 20 wt %) (serving as second thermoplastic material with a melt flow rate (R2) of 13 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (2) with a double-layer structure was obtained.

Next, the transmittance (%) and haze (%) of Composite film (2) were measured, and the results are shown in Table 1.

### Preparation Example 3

A material of the first layer was provided, wherein the material of the first layer was ethylene-propylene copolymer (commercially available from Formosa Plastics Corporation with a trade name of 3084H) (the amount of the ethylene monomer was about 10 wt %, based on the weight of the propylene monomer) (serving as first thermoplastic material with a melt flow rate (R1) of 8.5 g/10 min). A material of the second layer was provided, wherein the material of the second layer was styrene-ethylene-butylene-styrene block copolymer (SEBS) (commercially available from Asahi Kasei Corporation with a trade name of SOE™ S1605) (styrene/SEBS was 30 wt %) (serving as second thermoplastic material with a melt flow rate (R2) of 5 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (3) with a double-layer structure was obtained.

Next, the transmittance (%) and haze (%) of Composite film (3) were measured, and the results are shown in Table 1.

### Preparation Example 4

A material of the first layer was provided, wherein the material of the first layer was ethylene-propylene copolymer (commercially available from LCY Chemical Corp. with a trade name of 7101) (the amount of the ethylene monomer was about 10 wt %, based on the weight of the propylene monomer) (serving as first thermoplastic material with a melt flow rate (R1) of 1.3 g/10 min). A material of the second layer was provided, wherein the material of the second layer was ethylene-vinyl acetate copolymer (commercially available from USI Corporation with a trade name of UE4003) (the amount of vinyl acetate (VA content) was 40 wt %) (serving as second thermoplastic material with a melt flow rate (R2) of 3 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (4) with a double-layer structure was obtained.

Next, the transmittance (%) and haze (%) of Composite film (4) were measured, and the results are shown in Table 1.

### Preparation Example 5

A material of the first layer was provided, wherein the material of the first layer was ethylene-propylene copolymer (commercially available from LCY Chemical Corp. with a trade name of ST860K) (the amount of the ethylene monomer was less than about 4 wt %, based on the weight of the propylene monomer) (serving as first thermoplastic material with a melt flow rate (R1) of 48 g/10 min). A material of the second layer was provided, wherein the material of the second layer was styrene-ethylene-butylene-styrene block copolymer (SEBS) (commercially available from Wewill Inc. with a trade name of MD6951) (styrene/SEBS was 34 wt %) (serving as second thermoplastic material with a melt flow rate (R2) of 45 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (5) with a double-layer structure was obtained.

Next, the transmittance (%) and haze (%) of Composite film (5) were measured, and the results are shown in Table 1.

### Preparation Example 6

A material of the first layer was provided, wherein the material of the first layer was ethylene-propylene copolymer (commercially available from Formosa Plastics Corporation with a trade number of 3354) (the amount of the ethylene monomer was about 10 wt %, based on the weight of the propylene monomer) (serving as first thermoplastic material with a melt flow rate (R1) of 35 g/10 min). A material of the second layer was provided, wherein the material of the second layer was styrene-ethylene-butylene-styrene block copolymer (SEBS) (commercially available from Asahi Kasei Corporation with a trade name of Tuftec™ H1041) (styrene/SEBS was 30 wt %) (serving as second thermoplastic material with a melt flow rate (R2) of 5 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. Herein, since the first layer cannot continuously form a film on the second layer, it was therefore impossible to obtain a composite film with a double-layer structure.

### Preparation Example 7

A material of the first layer was provided, wherein the material of the first layer was ethylene-propylene copolymer (commercially available from Formosa Plastics Corporation with a trade name of RP3015) (the amount of the ethylene monomer was about 10 wt %, based on the weight of the propylene monomer) (serving as first thermoplastic material with a melt flow rate (R1) of 2 g/10 min). A material of the second layer was provided, wherein the material of the second layer was styrene-ethylene-butylene-styrene block copolymer (SEBS) (commercially available from Wewill Inc. with a trade name of MD6951) (styrene/SEBS was 34 wt %) (serving as second thermoplastic material with a melt flow rate (R2) of 45 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. Herein, since the second layer cannot continuously form a film on the first layer, it was therefore impossible to obtain a composite film with a double-layer structure.

TABLE 1

| | | | | first layer | | |
|---|---|---|---|---|---|---|
| | | | | thickness | | |
| | | | | (μm)/second | | |
| | first | second | | layer | | |
| | thermoplastic | thermoplastic | R1-R2 | thickness | transmittance | haze |
| | elastomer | elastomer | (g/10 min) | (μm) | (%) | (%) |
| Preparation | 3600N | MD6951 | 10 | 125/125 | 88.25 | 60.24 |
| Example 1 | | | | | | |
| Preparation | RP3015 | H1502 | −11 | 125/125 | 88.57 | 52.61 |
| Example 2 | | | | | | |
| Preparation | 3084H | S1605 | 3.5 | 125/125 | 89.46 | 72.95 |
| Example 3 | | | | | | |
| Preparation | 7101 | UE4003 | −1.7 | 125/125 | 90.38 | 71.26 |
| Example 4 | | | | | | |
| Preparation | ST860K | MD6951 | 3 | 125/125 | 90.59 | 10.98 |
| Example 5 | | | | | | |

| | | | | |
|---|---|---|---|---|
| Preparation | 3354 | H1041 | 30 | no composite film was obtained (a |
| Example 6 | | | | continuous first layer cannot be |
| | | | | formed) |
| Preparation | RP3015 | MD6951 | −43 | no composite film was obtained (a |
| Example 7 | | | | continuous second layer cannot be |
| | | | | formed) |

As shown in Table 1, when the melt flow rate (R1) of the first thermoplastic material and the melt flow rate (R2) of the second thermoplastic material conform to the equation: −11≤(R1−R2)≤11 (i.e., Preparation Examples 1-5), composite films with a double-layer structure can be formed using a co-extrusion process. When the polyethylene (PE) block content of the ethylene-propylene copolymer used as the first thermoplastic material is less than 7 wt % (i.e., the ethylene-propylene copolymer used is a random copolymer) (Preparation Example 5), the haze of the obtained composite film is less than 15%. Additionally, when the difference between the melt flow rate (R1) of the first thermoplastic material and the melt flow rate (R2) of the second thermoplastic material is too large (Preparation Examples 6 and 7), it is not possible to form a composite film with a double-layer structure using the co-extrusion process.

### Preparation Example 8

A material of the first layer was provided, wherein the material of the first layer included ethylene-propylene copolymer (commercially available from Formosa Plastics Corporation with a trade name of 3084H) (the amount of the ethylene monomer was about 10 wt %, based on the weight of the propylene monomer) (serving as first thermoplastic material with a melt flow rate (R1) of 8.5 g/10 min). A material of the second layer was provided, wherein the material of the second layer was styrene-ethylene-butylene-styrene block copolymer (SEBS) (commercially available from Asahi Kasei Corporation with a trade name of SOE™ S1605) (styrene/SEBS was 30 wt %) (serving as second thermoplastic material with a melt flow rate (R2) of 5 g/10 min) and a binder (commercially available from Cray Valley with a trade name of Cleartack® W140), wherein the weight ratio of the second thermoplastic material to the binder was 10:1.

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (6) with a double-layer structure was obtained.

Next, the transmittance (%) and haze (Hz) of Composite film (6) were measured, and the results are shown in Table 2.

### Preparation Example 9

Preparation Example 9 was performed in the same manner as in Preparation Example 8, except that the weight ratio of the second thermoplastic material to the binder was adjusted from 10:1 to 5:1, obtaining Composite film (7) with a double-layer structure. Next, the transmittance (%) and haze (%) of Composite film (7) were measured, and the results are shown in Table 2.

### Preparation Example 10

Preparation Example 10 was performed in the same manner as in Preparation Example 8, except that the weight ratio of the second thermoplastic material to the binder was adjusted from 10:1 to 5:3, obtaining Composite film (8) with a double-layer structure. Next, the transmittance (%) and haze (%) of Composite film (8) were measured, and the results are shown in Table 2.

### Preparation Example 11

Preparation Example 11 was performed in the same manner as in Preparation Example 8, except that the weight ratio of the second thermoplastic material to the binder was adjusted from 10:1 to 1:1, obtaining Composite film (9) with a double-layer structure. Next, the transmittance (%) and haze (%) of Composite film (9) were measured, and the results are shown in Table 2.

TABLE 2

| | weight ratio | | | |
|---|---|---|---|---|
| | of the second | first layer | | |
| | thermoplastic | thickness (μm)/ | | |
| | material to | second layer | transmittance | haze |
| | the binder | thickness (μm) | (%) | (%) |
| Preparation | 10:1 | 125/125 | 88.32 | 69.31 |
| Example 8 | | | | |
| Preparation | 5:1 | 125/125 | 88.84 | 72.59 |
| Example 9 | | | | |
| Preparation | 5:3 | 125/125 | 88.35 | 79.93 |
| Example 10 | | | | |
| Preparation | 1:1 | 125/125 | 86.83 | 81.16 |
| Example 11 | | | | |

### Preparation Example 12

A material of the first layer was provided, wherein the material of the first layer included ethylene-propylene copolymer (commercially available from Formosa Plastics Corporation with a trade name of 3084H) (the amount of the ethylene monomer was about 10 wt %, based on the weight of the propylene monomer) (serving as first thermoplastic material with a melt flow rate (R1) of 8.5 g/10 min) and first diffusion particle (silicon dioxide, particle size distribution D90 about 2 μm), wherein the amount of the first diffusion particle was 6 wt % (based on the total weight of the first thermoplastic material and the first diffusion particle). A material of the second layer was provided, wherein the material of the second layer included styrene-ethylene-butylene-styrene block copolymer (SEBS) (commercially available from Asahi Kasei Corporation with a trade name of SOE™ S1605) (styrene/SEBS was 30 wt %) (serving as second thermoplastic material with a melt flow rate (R2) of 5 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (10) with a double-layer structure was obtained.

Next, the transmittance (%) and haze (%) of Composite film (10) were measured, and the results are shown in Table 3.

### Preparation Example 13

Preparation Example 13 was performed in the same manner as in Preparation Example 12, except that the amount of the first diffusion particle was adjusted from 6 wt % to 14 wt %, obtaining Composite film (11) with a double-layer structure. Next, the transmittance (%) and haze (%) of Composite film (11) were measured, and the results are shown in Table 3.

### Preparation Example 14

Preparation Example 14 was performed in the same manner as in Preparation Example 12, except that the amount of the first diffusion particle was adjusted from 6 wt % to 24 wt %, obtaining Composite film (12) with a double-layer structure. Next, the transmittance (%) and haze (%) of Composite film (12) were measured, and the results are shown in Table 3.

### Preparation Example 15

Preparation Example 15 was performed in the same manner as in Preparation Example 12, except that the amount of the first diffusion particle was adjusted from 6 wt % to 34 wt %, obtaining Composite film (13) with a double-layer structure. Next, the transmittance (%) and haze (%) of Composite film (13) were measured, and the results are shown in Table 3.

### Preparation Example 16

A material of the first layer was provided, wherein the material of the first layer was ethylene-propylene copolymer (commercially available from LCY Chemical Corp. with a trade name of ST860K) (the amount of the ethylene monomer was less than about 4 wt %, based on the weight of the propylene monomer) (serving as first thermoplastic material with a melt flow rate (R1) of 48 g/10 min) and first diffusion particle (silicon dioxide, particle size distribution D90 about 2 μm), wherein the amount of the first diffusion particle was 24% (based on the total weight of the first thermoplastic material and the first diffusion particle). A material of the second layer was provided, wherein the material of the second layer was styrene-ethylene-butylene-styrene block copolymer (SEBS) (commercially available from Wewill Inc. with a trade name of MD6951) (styrene/SEBS was 34 wt %) (serving as second thermoplastic material with a melt flow rate (R2) of 45 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (14) with a double-layer structure was obtained.

Next, the transmittance (%) and haze (%) of Composite film (14) were measured, and the results are shown in Table 3.

TABLE 3

| | | | | first layer | | |
|---|---|---|---|---|---|---|
| | | | first | thickness | | |
| | first | second | diffusion | (μm)/second | | |
| | thermoplastic | thermoplastic | particle | layer thickness | transmittance | haze |
| | elastomer | elastomer | (wt %) | (μm) | (%) | (%) |
| Preparation | 3084H | S1605 | 6 | 125/125 | 88.14 | 82.67 |
| Example 12 | | | | | | |
| Preparation | 3084H | S1605 | 14 | 125/125 | 87.28 | 85.90 |
| Example 13 | | | | | | |
| Preparation | 3084H | S1605 | 24 | 125/125 | 87.08 | 88.64 |
| Example 14 | | | | | | |
| Preparation | 3084H | S1605 | 34 | 125/125 | 82.09 | 93.50 |
| Example 15 | | | | | | |
| Preparation | ST860K | MD6951 | 24 | 125/125 | 90.32 | 38.51 |
| Example 16 | | | | | | |

As shown in Table 3, when the material of the first layer further includes diffusion particles (i.e., Preparation Examples 12-15), the haze of the composite film can be increased while maintaining good transparency of the composite film. Additionally, when the polyethylene (PE) block content of the ethylene-propylene copolymer used as the first thermoplastic material is less than 7 wt % (i.e., the ethylene-propylene copolymer is a random copolymer), even with the addition of a large amount of diffusion particles in the first layer, it is still not possible to raise the haze of the composite film (i.e., Preparation Example 16) to be over 60%.

### Preparation Example 17

A material of the first layer was provided, wherein the material of the first layer included ethylene-propylene copolymer (commercially available from Formosa Plastics Corporation with a trade name of 3084H) (the amount of the ethylene monomer was about 10 wt %, based on the weight of the propylene monomer) (serving as first thermoplastic material with a melt flow rate (R1) of 8.5 g/10 min), first diffusion particle (silicon dioxide, particle size distribution D90 about 2 μm), and second diffusion particle (titanium oxide, particle size distribution D90 about 300 nm), wherein the amount of the first diffusion particle was 6 wt % (based on the total weight of the first thermoplastic material, first diffusion particle and second diffusion particle), and the amount of the second diffusion particle was 0.05 wt % (based on the total weight of the first thermoplastic material, first diffusion particle and second diffusion particle). A material of the second layer was provided, wherein the material of the second layer included styrene-ethylene-butylene-styrene block copolymer (SEBS) (commercially available from Asahi Kasei Corporation with a trade name of SOE™ S1605) (styrene/SEBS was 30 wt %) (serving as second thermoplastic material with a melt flow rate (R2) of 5 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (15) with a double-layer structure was obtained.

Next, the transmittance (%) and haze (%) of Composite film (15) were measured, and the results are shown in Table 4.

### Preparation Example 18

Preparation Example 18 was performed in the same manner as in Preparation Example 17, except that the amount of the second diffusion particle was adjusted from 0.05 wt % to 0.1 wt %, obtaining Composite film (16) with a double-layer structure. Next, the transmittance (%) and haze (%) of Composite film (16) were measured, and the results are shown in Table 4.

### Preparation Example 19

Preparation Example 19 was performed in the same manner as in Preparation Example 17, except that the amount of the second diffusion particle was adjusted from 0.05 wt % to 0.15 wt %, obtaining Composite film (17) with a double-layer structure. Next, the transmittance (%) and haze (%) of Composite film (17) were measured, and the results are shown in Table 4.

TABLE 4

| | | | first layer | | |
|---|---|---|---|---|---|
| | | | thickness | | |
| | first | second | (μm)/second | | |
| | diffusion | diffusion | layer | | |
| | particle | particle | thickness | transmittance | haze |
| | (wt %) | (wt %) | (μm) | (%) | (%) |
| Preparation | 6 | 0.05 | 125/125 | 87.26 | 92.17 |
| Example 17 | | | | | |
| Preparation | 6 | 0.1 | 125/125 | 86.78 | 97.29 |
| Example 18 | | | | | |
| Preparation | 6 | 0.15 | 125/125 | 82.24 | 98.38 |
| Example 19 | | | | | |

As shown in Table 4, when the material of the first layer further includes two diffusion particles with different particle sizes (i.e., Preparation Examples 17-19), the haze of the obtained composite film can be further increased while maintaining good transparency of the composite film.

### Preparation Example 20

A material of the first layer was provided, wherein the material of the first layer was polyethylene terephthalate (PET) (commercially available from DuPont with a trade name of RE5264) (serving as first thermoplastic material with a melt flow rate (R1) of 27 g/10 min). A material of the second layer was provided, wherein the material of the second layer was styrene-ethylene-butylene-styrene block copolymer (SEBS) (commercially available from Wewill Inc. with a trade name of MD6951) (styrene/SEBS was 34 wt %) (serving as second thermoplastic material with a melt flow rate (R2) of 45 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. Herein, since the first layer cannot continuously form a film on the second layer, it was therefore impossible to obtain a composite film with a double-layer structure.

### Preparation Example 21

A material of the first layer was provided, wherein the material of the first layer was polyethylene terephthalate (PET) (commercially available from Nanya Plastic Corporation with a trade name of 4410G6) (serving as first thermoplastic material with a melt flow rate (R1) of 15 g/10 min). A material of the second layer was provided, wherein the material of the second layer was styrene-ethylene-butylene-styrene block copolymer (SEBS) (commercially available from Asahi Kasei Corporation with a trade name of SOE™ S1605) (styrene/SEBS was 30 wt %) (serving as second thermoplastic material with a melt flow rate (R2) of 5 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (18) with a double-layer structure was obtained. Next, the transmittance (%) of Composite film (18) was measured, and the result is shown in Table 5.

### Preparation Example 22

A material of the first layer was provided, wherein the material of the first layer was polyethylene terephthalate (PET) (commercially available from Nanya Plastic Corporation with a trade name of 380R) (serving as first thermoplastic material with a melt flow rate (R1) of 2.5 g/10 min). A material of the second layer was provided, wherein the material of the second layer was styrene-ethylene-butylene-styrene block copolymer (SEBS) (commercially available from Asahi KASEI with a trade name of H1502, styrene/SEBS was 20 wt %) (serving as second thermoplastic material with a melt flow rate (R2) of 13 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (19) with a double-layer structure was obtained. Next, the transmittance (%) of Composite film (19) was measured, and the result is shown in Table 5.

TABLE 5

| | | | | first layer | |
|---|---|---|---|---|---|
| | | | | thickness | |
| | | | | (μm)/ | |
| | first | second | | second | |
| | thermo- | thermo- | | layer | trans- |
| | plastic | plastic | R1-R2 | thickness | mittance |
| | material | elastomer | (g/10 min) | (μm) | (%) |
| Preparation | RE5264 | MD6951 | 18 | no composite | |
| Example 20 | | | | film was obtained | |
| | | | | (a continuous | |
| | | | | first layer | |
| | | | | cannot be formed) | |
| Preparation | 4410G6 | S1605 | 10 | 125/125 | 89.17 |
| Example 21 | | | | | |
| Preparation | 380R | H1502 | −10.5 | 125/125 | 89.63 |
| Example 22 | | | | | |

As shown in Table 5, when the melt flow rate R1 of the first thermoplastic material (polyethylene terephthalate) and the melt flow rate R2 of the second thermoplastic material satisfy the relationship −11≤(R1−R2)≤11 (i.e., Preparation Examples 21 and 22), a composite film with a double-layer structure can be formed using a co-extrusion process. In contrast, when the difference between the melt flow rates R1 and R2 is too large (i.e. Preparation Example 20), a composite film with a double-layer structure cannot be formed by the co-extrusion process.

### Preparation Example 23

A material of the first layer was provided, wherein the material of the first layer included polyethylene terephthalate (PET) (commercially available from Nanya Plastic Corporation with a trade name of 4410G6) (serving as first thermoplastic material with a melt flow rate (R1) of 15 g/10 min) and first diffusion particle (silicon dioxide, particle size distribution D90 about 2 μm), wherein the amount of the first diffusion particle was 2 wt % (based on the total weight of the first thermoplastic material and the first diffusion particle). A material of the second layer was provided, wherein the material of the second layer was styrene-ethylene-butylene-styrene block copolymer (SEBS) (commercially available from Asahi Kasei Corporation with a trade name of SOE™ S1605) (styrene/SEBS was 30 wt %) (serving as second thermoplastic material with a melt flow rate (R2) of 5 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (20) with a double-layer structure was obtained. Next, the transmittance (%) and haze (%) of Composite film (20) were measured, and the results are shown in Table 6.

### Preparation Example 24

Preparation Example 24 was performed in the same manner as in Preparation Example 23, except that the amount of the first diffusion particle was adjusted from 2 wt % to 7 wt %, obtaining Composite film (21) with a double-layer structure. Next, the transmittance (%) and haze (%) of Composite film (21) were measured, and the results are shown in Table 6.

### Preparation Example 25

Preparation Example 25 was performed in the same manner as in Preparation Example 23, except that the amount of the first diffusion particle was adjusted from 2 wt % to 15 wt %, obtaining Composite film (22) with a double-layer structure Next, the transmittance (%) and haze (%) of Composite film (22) were measured, and the results are shown in Table 6.

### Preparation Example 26

A material of the first layer was provided, wherein the material of the first layer included polyethylene terephthalate (PET) (commercially available from Nanya Plastic Corporation with a trade name of 380R) (serving as first thermoplastic material with a melt flow rate (R1) of 2.5 g/10 min) and first diffusion particle (silicon dioxide, particle size distribution D90 about 2 μm), wherein the amount of the first diffusion particle was 9 wt % (based on the total weight of the first thermoplastic material and the first diffusion particle). A material of the second layer was provided, wherein the material of the second layer was styrene-ethylene-butylene-styrene block copolymer (SEBS) (commercially available from Asahi KASEI with a trade name of H1502, styrene/SEBS was 20 wt %) (serving as second thermoplastic material with a melt flow rate (R2) of 13 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (23) with a double-layer structure was obtained. Next, the transmittance (%) and haze (%) of Composite film (23) were measured, and the results are shown in Table 6.

### Preparation Example 27

Preparation Example 27 was performed in the same manner as in Preparation Example 26, except that the amount of the first diffusion particle was adjusted from 9 wt % to 13 wt %, obtaining Composite film (24) with a double-layer structure. Next, the transmittance (0%) and haze (0%) of Composite film (24) were measured, and the results are shown in Table 6.

TABLE 6

| | | | | first layer | | |
|---|---|---|---|---|---|---|
| | | | | thickness | | |
| | first | second | first | (μm)/second | | |
| | thermo- | thermo- | diffusion | layer | trans- | |
| | plastic | plastic | particle | thickness | mittance | haze |
| | material | material | (wt %) | (μm) | (%) | (%) |
| Preparation | 4410G6 | S1605 | 2 | 125/125 | 88.90 | 65.63 |
| Example 23 | | | | | | |
| Preparation | 4410G6 | S1605 | 7 | 125/125 | 86.23 | 86.17 |
| Example 24 | | | | | | |
| Preparation | 4410G6 | S1605 | 15 | 125/125 | 85.19 | 92.10 |
| Example 25 | | | | | | |
| Preparation | 380R | H1502 | 9 | 125/125 | 86.50 | 83.72 |
| Example 26 | | | | | | |
| Preparation | 380R | H1502 | 13 | 125/125 | 85.63 | 90.13 |
| Example 27 | | | | | | |

As shown in Table 6, when the material of the first layer (polyethylene terephthalate) further included diffusion particles (i.e., Preparation Examples 23-27), the haze of the composite film can be increased without compromising its transmittance.

### Preparation Example 28

A material of the first layer was provided, wherein the material of the first layer included polyethylene terephthalate (PET) (commercially available from Nanya Plastic Corporation with a trade name of 380R) (serving as first thermoplastic material with a melt flow rate (R1) of 2.5 g/10 min), first diffusion particle (silicon dioxide, particle size distribution D90 about 2 μm), and second diffusion particle (titanium oxide, particle size distribution D90 about 300 nm), wherein the amount of the first diffusion particle was 9 wt % (based on the total weight of the first thermoplastic material, first diffusion particle and second diffusion particle), and the amount of the second diffusion particle was 0.01 wt % (based on the total weight of the first thermoplastic material, first diffusion particle and second diffusion particle). A material of the second layer was provided, wherein the material of the second layer was styrene-ethylene-butylene-styrene block copolymer (SEBS) (commercially available from Asahi KASEI with a trade name of H1502, styrene/SEBS was 20 wt %) (serving as second thermoplastic material with a melt flow rate (R2) of 13 g/10 min).

Next, the material of the first layer and the material of the second layer were separately added into a twin-screw extruder to undergo high-temperature melting at a temperature between 190° C. and 230° C. and a screw speed between 250 rpm and 300 rpm. The molten material was introduced into a dual-layer co-extrusion die with an internal flow channel design and then extruded. After cooling, film winding, and collection, Composite film (25) with a double-layer structure was obtained. Next, the transmittance (%) and haze (%) of Composite film (25) were measured, and the results are shown in Table 7.

### Preparation Example 29

Preparation Example 29 was performed in the same manner as in Preparation Example 28, except that the amount of the second diffusion particle was adjusted from 0.01 wt % to 0.05 wt %, obtaining Composite film (26) with a double-layer structure. Next, the transmittance (%) and haze (%) of Composite film (26) were measured, and the results are shown in Table 7.

TABLE 7

| | | | first layer | | |
|---|---|---|---|---|---|
| | | | thickness | | |
| | first | second | (μm)/second | | |
| | diffusion | diffusion | layer | | |
| | particle | particle | thickness | transmittance | haze |
| | (wt %) | (wt %) | (μm) | (%) | (%) |
| Preparation | 9 | 0 | 125/125 | 86.50 | 83.72 |
| Example 26 | | | | | |
| Preparation | 9 | 0.01 | 125/125 | 86.22 | 86.90 |
| Example 28 | | | | | |
| Preparation | 9 | 0.05 | 125/125 | 85.22 | 93.79 |
| Example 29 | | | | | |

As shown in Table 7, when the material of the first layer further includes two types of diffusion particles with different particle sizes (i.e., Preparation Examples 28 and 29), the haze of the composite film can be further increased without compromising its transmittance.

### Preparation and Evaluation of Packaging Structure

### Examples 1-5

The composite films (1)-(5) of Preparation Examples 1-5 were applied to the packaging of light-emitting diode (LED) units. First, a substrate was provided (material: PCB and white paint, thickness: 0.05 cm, size: 0.13 cm×0.03 cm×0.009 cm).

Next, the composite film was disposed on the substrate to cover the LED unit, wherein the second layer of the composite film (i.e., the layer containing the second thermoplastic material) was in contact with the substrate. The obtained structure was introduced into a thermocompression molding machine (available under the trade designation of VLP-100, commercially available from Huo Quan Machinery Co., Ltd.) for thermocompression bonding, wherein the molding temperature ranged between 130° C. and 150° C. After cooling, LED packaging structures (1)-(5) were obtained.

Next, the luminous uniformity of the LED packaging structure, and the adhesion of the composite film were measured, and the results are shown in Table 8. The luminous uniformity test was conducted using a luminance meter (PR-655, TITAN Electro-Optics Co., LTD.). The test was performed at room temperature to determine the luminous uniformity value (U) below the module, wherein U=(I_{dark}/I_{brightness})×100%. The adhesion test was conducted via a tensile testing machine (QC-513A2, COMETECH TESTING MACHINES CO., LTD.). The test conditions involve stretching the adhesive and substrate at 180° at room temperature and measuring the peel adhesion between the adhesive (25 mm width) and substrate. The evaluation was performed according to the method specified in ASTM D3330.

Next, a stability test of the LED packaging structure was performed. If the LED packaging structure continued to function normally after the test, and no bubbles formed between the substrate and the composite film, and no collapse of the composite film, it was considered to have passed the test and was marked with an “O.” Conversely, failures were marked with an “X,” and the results are shown in Table 8. The steps of the stability test were as follows: First, the LED packaging structure was placed in an environment with 85% relative humidity and a temperature of 85° C. for 300 hours. Next, the LED packaging structure was placed in an environment with 85% relative humidity and a temperature of −40° C. for 300 hours. Finally, the LED packaging structure was placed in an environment with 85% relative humidity and a temperature of 100° C. for 300 hours.

Next, a debonding test of the LED packaging structure was performed. After the debonding process, if the composite film could be completely removed from the substrate without pulling up the LED, it was considered to have passed the test and was marked with an “O.” Conversely, failures were marked with an “X” (such as if the composite film could not be completely removed, the composite film cracked during removal, or the LED was pulled up), and the results are shown in Table 8. The steps of the debonding test were as follows: the composite film was heated with a hot air gun (heating temperature between 100° C. and 120° C., heating time approximately 15 minutes) and then peeled and removed the composite film.

TABLE 8

| | | first | second | | | | |
|---|---|---|---|---|---|---|---|
| | | thermo- | thermo- | luminous | peel | | |
| | composite | plastic | plastic | uniformity | adhesion | stability | debonding |
| | film | material | material | (%) | (gf/25 mm) | test | test |
| Example 1 | Composite | 3600N | MD6951 | 43.19 | 1002 | ◯ | ◯ |
| | film (1) | | | | | | |
| Example 2 | Composite | RP3015 | H1502 | 49.78 | 937 | | |
| | film (2) | | | | | ◯ | ◯ |
| Example 3 | Composite | 3084H | S1605 | 59.95 | 1298 | | |
| | film (3) | | | | | ◯ | ◯ |
| Example 4 | Composite | 7101 | UE4003 | 51.22 | 1035 | | |
| | film (4) | | | | | ◯ | ◯ |
| Example 5 | Composite | ST860K | MD6951 | 14.3 | 916 | | |
| | film (5) | | | | | | |

As shown in Table 8, the composite film of the disclosure can be stably adhered to the, resulting in a packaging structure (such as an LED packaging structure) with good luminous uniformity and stability in high-temperature and high-humidity environments. In addition, when the first thermoplastic material is an ethylene-propylene copolymer and the polyethylene (PE) block content of the first thermoplastic material used in the composite film is in the range of 7 wt % 0 to 15 wt %, the packaging structure exhibits even better luminous uniformity.

### Examples 6-9

The Composite films (6)-(9) of Preparation Examples 8-11 were applied to the packaging of light-emitting diode (LED) units. First, a substrate was provided (material: PCB and white paint, thickness: 0.05 cm, size: 0.13 cm×0.03 cm×0.009 cm).

Next, the composite film was disposed on the substrate to cover the LED unit, wherein the second layer of the composite film (i.e., the layer containing the second thermoplastic material) was in contact with the substrate. The obtained structure was introduced into a compression molding machine (available under the trade designation of VLP-100, commercially available from Huo Quan Machinery Co., Ltd.) for thermocompression bonding, wherein the molding temperature ranged between 130° C. and 150° C. After cooling, LED packaging structures (6)-(9) were obtained.

Next, the luminous uniformity of the LED packaging structure, and the adhesion of the composite film were measured, and the results are shown in Table 9.

Next, a stability test of the LED packaging structure was performed. If the LED packaging structure continued to function normally after the test, and no bubbles formed between the substrate and the composite film, and no collapse of the composite film, it was considered to have passed the test and was marked with an “O.” Conversely, failures were marked with an “X,” and the results are shown in Table 9.

Next, a debonding test of the LED packaging structure was performed. After the debonding process, if the composite film could be completely removed from the substrate without pulling up the LED, it was considered to have passed the test and was marked with an “O.” Conversely, failures were marked with an “X” (such as if the composite film could not be completely removed, the composite film cracked during removal, or the LED was pulled up), and the results are shown in Table 9.

TABLE 9

| | | weight ratio | | | | |
|---|---|---|---|---|---|---|
| | | of second | | | | |
| | | thermoplastic | luminous | | | |
| | composite | material to | uniformity | peel adhesion | | debonding |
| | film | binder | (%) | (gf/25 mm) | stability test | test |
| Example 3 | Composite | No binder | 59.95 | 1298 | ◯ | ◯ |
| | film (3) | | | | | |
| Example 6 | Composite | 10:1 | 66.47 | 2157 | ◯ | ◯ |
| | film (6) | | | | | |
| Example 7 | Composite | 5:1 | 68.30 | 2268 | ◯ | ◯ |
| | film (7) | | | | | |
| Example 8 | Composite | 5:3 | 71.60 | 2297 | ◯ | ◯ |
| | film (8) | | | | | |
| Example 9 | Composite | 1:1 | 78.10 | unable to | — | X (removed |
| | film (9) | | | measure | | incompletely) |
| | | | | (partially | | |
| | | | | adhered to | | |
| | | | | the substrate, | | |
| | | | | unable to be | | |
| | | | | completely | | |
| | | | | removed) | | |

As shown in Table 9, in comparison with Example 3, due to the use of the second thermoplastic material and further addition of a binder in the second layer of the composite film used in Examples 6-8, the adhesion between the composite film and the substrate in the LED packaging structure is further enhanced. In addition, when the weight ratio of the binder to the second thermoplastic material is 1:1, it is observed that Composite film (9) could not be completely removed from the packaging substrate after the debonding process, resulting in residual adhesive.

### Examples 10-13

The Composite films (10)-(13) of Preparation Examples 12-15 were applied to the packaging of light-emitting diode (LED) units. First, a substrate was provided (material: PCB and white paint, thickness: 0.05 cm, size: 0.13 cm×0.03 cm×0.009 cm).

Next, the composite film was disposed on the substrate to cover the LED unit, wherein the second layer of the composite film (i.e., the layer containing the second thermoplastic material) was in contact with the substrate. The obtained structure was introduced into a thermocompression molding machine (available under the trade designation of VLP-100, commercially available from Huo Quan Machinery Co., Ltd.) for thermocompression bonding, wherein the molding temperature ranged between 130° C. and 150° C. After cooling, LED packaging structures (10)-(13) were obtained.

Next, the luminous uniformity of the LED packaging structure, and the adhesion of the composite film were measured, and the results are shown in Table 10.

Next, a stability test of the LED packaging structure was performed. If the LED packaging structure continued to function normally after the test, and no bubbles formed between the substrate and the composite film, and no collapse of the composite film, it was considered to have passed the test and was marked with an “O.” Conversely, failures were marked with an “X,” and the results are shown in Table 10.

Next, a debonding test of the LED packaging structure was performed. After the debonding process, if the composite film could be completely removed from the substrate without pulling up the LED, it was considered to have passed the test and was marked with an “O.” Conversely, failures were marked with an “X” (such as if the composite film could not be completely removed, the composite film cracked during removal, or the LED was pulled up), and the results are shown in Table 10.

TABLE 10

| | | first diffusion | luminous | | | |
|---|---|---|---|---|---|---|
| | composite | particle | uniformity | peel adhesion | | debonding |
| | film | (wt %) | (%) | (gf/25 mm) | stability test | test |
| Example 3 | Composite | No diffusion | 59.95 | 1298 | ◯ | ◯ |
| | film (3) | particle | | | | |
| Example 10 | Composite | 6 | 77.2 | 2168 | ◯ | ◯ |
| | film (10) | | | | | |
| Example 11 | Composite | 14 | 79.8 | 1907 | ◯ | ◯ |
| | film (11) | | | | | |
| Example 12 | Composite | 24 | 85.2 | 1293 | ◯ | ◯ |
| | film (12) | | | | | |
| Example 13 | Composite | 34 | 80.3 | 1129 | X (composite | X (composite |
| | film (13) | | | | film cracks) | film cracks) |

As shown in Table 10, in comparison with Example 3, the use of the first thermoplastic material in the first layer of the composite film in Examples 10-12, along with the addition of a first diffusion particle, further improves the luminous uniformity of the obtained light-emitting diode packaging structure. In addition, when the content of the first diffusion particle increases to 34 wt %, it is observed that Composite film (13) failed the stability test and debonding test.

### Examples 14-16

The Composite films (15)-(17) of Preparation Examples 17-19 were applied to the packaging of light-emitting diode (LED) units. First, a substrate was provided (material: PCB and white paint, thickness: 0.05 cm, size: 0.13 cm×0.03 cm×0.009 cm).

Next, the composite film was disposed on the substrate to cover the LED unit, wherein the second layer of the composite film (i.e., the layer containing the second thermoplastic material) was in contact with the substrate. The obtained structure was introduced into a thermocompression molding machine (available under the trade designation of VLP-100, commercially available from Huo Quan Machinery Co., Ltd.) for thermocompression bonding, wherein the molding temperature ranged between 130° C. and 150° C. After cooling, LED packaging structures (14)-(16) were obtained.

Next, the luminous uniformity of the LED packaging structure, and the adhesion of composite film were measured, and the results are shown in Table 11.

Next, a stability test of the LED packaging structure was performed. If the LED packaging structure continued to function normally after the test, and no bubbles formed between the substrate and the composite film, and no collapse of the composite film, it was considered to have passed the test and was marked with an “O.” Conversely, failures were marked with an “X,” and the results are shown in Table 11.

Next, a debonding test of the LED packaging structure was performed. After the debonding process, if the composite film could be completely removed from the substrate without pulling up the LED, it was considered to have passed the test and was marked with an “O.” Conversely, failures were marked with an “X” (such as if the composite film could not be completely removed, the composite film cracked during removal, or the LED was pulled up), and the results are shown in Table 11.

TABLE 11

| | | first | second | luminous | peel | | |
|---|---|---|---|---|---|---|---|
| | | diffusion | diffusion | uniformity | adhesion | | |
| | composite | particle | particle | (%) | (gf/25 | stability | debonding |
| | film | (wt %) | (wt %) | | mm) | test | test |
| Example | Composite | 6 | No second | 77.2 | 2168 | ◯ | ◯ |
| 10 | film (10) | | diffusion | | | | |
| | | | particle | | | | |
| Example | Composite | 6 | 0.05 | 85.7 | 1779 | ◯ | ◯ |
| 14 | film (15) | | | | | | |
| Example | Composite | 6 | 0.1 | 87.9 | 1593 | ◯ | ◯ |
| 15 | film (16) | | | | | | |
| Example | Composite | 6 | 0.15 | 82.6 | 1324 | ◯ | ◯ |
| 16 | film (17) | | | | | | |

As shown in Table 11, in comparison with Example 10, the composite film used in Examples 14-16, which incorporates a first thermoplastic material in the first layer along with diffusion particles of distinct particle sizes, further improves the luminous uniformity of the obtained light-emitting diode packaging structure.

### Comparative Example 1

First, a substrate was provided (material: PCB and white paint, thickness: 0.05 cm, size: 0.13 cm×0.03 cm×0.009 cm).

Next, Composite film (3) of Preparation Example 3 was disposed on the substrate to cover the LED unit, wherein the first layer of the composite film (i.e., the layer containing the first thermoplastic material) was in contact with the substrate. Next, the obtained structure was introduced into a thermocompression molding machine (available under the trade designation of VLP-100, commercially available from Huo Quan Machinery Co., Ltd.) for thermocompression bonding, wherein the molding temperature ranged between 130° C. and 150° C. After cooling, it was observed that the composite film could not adhere to the substrate.

### Examples 17 and 18

The Composite films (18) and (19) of Preparation Examples 21 and 22 were applied to the packaging of light-emitting diode (LED) units. First, a substrate was provided (material: PCB and white paint, thickness: 0.05 cm, size: 0.13 cm×0.03 cm×0.009 cm).

Next, the composite film was disposed on the substrate to cover the LED unit, wherein the second layer of the composite film (i.e., the layer containing the second thermoplastic material) was in contact with the substrate. The obtained structure was introduced into a thermocompression molding machine (available under the trade designation of VLP-100, commercially available from Huo Quan Machinery Co., Ltd.) for thermocompression bonding, wherein the molding temperature ranged between 130° C. and 150° C. After cooling, LED packaging structures (17) and (18) were obtained.

Next, the luminous uniformity of the LED packaging structure, and the adhesion of composite film were measured, and the results are shown in Table 12.

Next, a stability test of the LED packaging structure was performed. If the LED packaging structure continued to function normally after the test, and no bubbles formed between the substrate and the composite film, and no collapse of the composite film, it was considered to have passed the test and was marked with an “O.” Conversely, failures were marked with an “X,” and the results are shown in Table 12.

Next, a debonding test of the LED packaging structure was performed. After the debonding process, if the composite film could be completely removed from the substrate without pulling up the LED, it was considered to have passed the test and was marked with an “O.” Conversely, failures were marked with an “X” (such as if the composite film could not be completely removed, the composite film cracked during removal, or the LED was pulled up), and the results are shown in Table 12.

TABLE 12

| | | first | second | luminous | peel | | |
|---|---|---|---|---|---|---|---|
| | composite | thermoplastic | thermoplastic | uniformity | adhesion | stability | debonding |
| | film | material | material | (%) | (gf/25 mm) | test | test |
| Example | Composite | 4410G6 | S1605 | 52.60 | 866 | ◯ | ◯ |
| 17 | (18) | | | | | | |
| Example | Composite | 380R | H1502 | 21.7 | 837 | ◯ | ◯ |
| 18 | (19) | | | | | | |

As shown in Table 12, the composite film of the disclosure can be stably adhered onto the packaging substrate, enabling the packaging structure (e.g., a light-emitting diode packaging structure) to exhibit good luminous uniformity. It also demonstrates stability under high-temperature and high-humidity conditions and can be completely removed from the packaging substrate.

### Examples 19-23

The Composite films (20)-(24) of Preparation Examples 23-27 were applied to the packaging of light-emitting diode (LED) units. First, a substrate was provided (material: PCB and white paint, thickness: 0.05 cm, size: 0.13 cm×0.03 cm×0.009 cm).

Next, the composite film was disposed on the substrate to cover the LED unit, wherein the second layer of the composite film (i.e., the layer containing the second thermoplastic material) was in contact with the substrate. The obtained structure was introduced into a thermocompression molding machine (available under the trade designation of VLP-100, commercially available from Huo Quan Machinery Co., Ltd.) for thermocompression bonding, wherein the molding temperature ranged between 130° C. and 150° C. After cooling, LED packaging structures (19)-(23) were obtained.

Next, the luminous uniformity of the LED packaging structure, and the adhesion of composite film were measured, and the results are shown in Table 13.

Next, a stability test of the LED packaging structure was performed. If the LED packaging structure continued to function normally after the test, and no bubbles formed between the substrate and the composite film, and no collapse of the composite film, it was considered to have passed the test and was marked with an “O.” Conversely, failures were marked with an “X,” and the results are shown in Table 13.

Next, a debonding test of the LED packaging structure was performed. After the debonding process, if the composite film could be completely removed from the substrate without pulling up the LED, it was considered to have passed the test and was marked with an “O.” Conversely, failures were marked with an “X” (such as if the composite film could not be completely removed, the composite film cracked during removal, or the LED was pulled up), and the results are shown in Table 13.

TABLE 13

| | | amount of | | | | |
|---|---|---|---|---|---|---|
| | | the first | | | | |
| | | diffusion | luminous | peel | | |
| | composite | particle | uniformity | adhesion | | debonding |
| | film | (wt %) | (%) | (gf/25 mm) | stability test | test |
| Example 19 | Composite | 2 | 68.9 | 1802 | ◯ | ◯ |
| | film (20) | | | | | |
| Example 20 | Composite | 7 | 85.8 | 1467 | ◯ | ◯ |
| | film (21) | | | | | |
| Example 21 | Composite | 15 | 83.6 | 1015 | ◯ | ◯ |
| | film (22) | | | | | |
| Example 22 | Composite | 9 | 69.2 | 1609 | ◯ | ◯ |
| | film (23) | | | | | |
| Example 23 | Composite | 13 | 82.5 | 1288 | ◯ | ◯ |
| | film (24) | | | | | |

As shown in Table 13, the composite film used in Examples 19−23, which incorporates a first thermoplastic material in the first layer along with the addition of a first diffusion particle, further improves the luminous uniformity of the obtained light-emitting diode packaging structure.

### Examples 24 and 25

The Composite films (25) and (26) of Preparation Examples 28 and 29 were applied to the packaging of light-emitting diode (LED) units. First, a substrate was provided (material: PCB and white paint, thickness: 0.05 cm, size: 0.13 cm×0.03 cm×0.009 cm).

Next, the composite film was disposed on the substrate to cover the LED unit, wherein the second layer of the composite film (i.e., the layer containing the second thermoplastic material) was in contact with the substrate. The obtained structure was introduced into a thermocompression molding machine (available under the trade designation of VLP-100, commercially available from Huo Quan Machinery Co., Ltd.) for thermocompression bonding, wherein the molding temperature ranged between 130° C. and 150° C. After cooling, LED packaging structures (24) and (25) were obtained.

Next, the luminous uniformity of the LED packaging structure, and the adhesion of composite film were measured, and the results are shown in Table 14.

Next, a stability test of the LED packaging structure was performed. If the LED packaging structure continued to function normally after the test, and no bubbles formed between the substrate and the composite film, and no collapse of the composite film, it was considered to have passed the test and was marked with an “O.” Conversely, failures were marked with an “X,” and the results are shown in Table 14.

Next, a debonding test of the LED packaging structure was performed. After the debonding process, if the composite film could be completely removed from the substrate without pulling up the LED, it was considered to have passed the test and was marked with an “O.” Conversely, failures were marked with an “X” (such as if the composite film could not be completely removed, the composite film cracked during removal, or the LED was pulled up), and the results are shown in Table 14.

TABLE 14

| | | amount of | amount of | | | | |
|---|---|---|---|---|---|---|---|
| | | the first | the second | | | | |
| | | diffusion | diffusion | luminous | peel | | |
| | composite | particle | particle | uniformity | adhesion | stability | debonding |
| | film | (wt %) | (wt %) | (%) | (gf/25 mm) | test | test |
| Example | Composite | 9 | 1 | 77.2 | 2168 | ◯ | ◯ |
| 24 | film (25) | | | | | | |
| Example | Composite | 9 | 0.05 | 85.7 | 1779 | ◯ | ◯ |
| 25 | film (26) | | | | | | |

As shown in Table 14, the composite film used in Examples 24 and 25 which incorporates a first thermoplastic material in the first layer along with diffusion particles of distinct particle sizes, further improves the luminous uniformity of the obtained light-emitting diode packaging structure.

Accordingly, due to the specific structure and ingredients of the composite film, the composite film of the disclosure may be prepared through a co-extrusion process, thereby significantly simplifying the process and reducing production costs. In addition, the composite film of the disclosure has high transmittance (such as transmittance greater than or equal to 80%), high haze (such as haze greater than or equal to 60%), high stability, and high adhesion (the peel adhesion between the composite film and the substrate ranging from 800 gf/25 mm to 2500 gf/25 mm), making it very suitable for use as an encapsulant in packaging structures (such as those configured on substrates with electronic components). Furthermore, due to the composite film, the packaging structure of the disclosure can be removed using a debonding process without damaging the electronic components on the substrate. As a result, the reworkability of the packaging structure and product yield can be improved.

It will be clear that various modifications and variations can be made to the disclosed methods and materials. It is intended that the specification and examples be considered as exemplary only, with the true scope of the disclosure being indicated by the following claims and their equivalents.

What is claimed is:

1. A packaging structure, comprising:
a substrate;
a plurality of light-emitting elements disposed on the substrate; and
a composite film disposed on the substrate to cover the light-emitting elements, wherein the composite film comprises:
a first layer, wherein the first layer comprises a first thermoplastic material, wherein a melt flow rate of the first thermoplastic material is R1, wherein the first thermoplastic material is an ethylene-propylene copolymer, polyethylene terephthalate, or a combination thereof; and
a second layer, wherein the second layer comprises a second thermoplastic material, wherein a melt flow rate of the second thermoplastic material is R2, and −11≤(R1−R2)≤11, wherein the second thermoplastic material 12 is a styrene-ethylene-butylene-styrene block copolymer, an ethylene-13 vinyl acetate copolymer, or a combination thereof.

2. The packaging structure as claimed in claim 1, wherein the second layer of the composite film contacts the plurality of light-emitting elements.

3. The packaging structure as claimed in claim 1, wherein each light-emitting element has a bottom surface, a top surface and a side surface, wherein the bottom surface of each light-emitting element contacts the substrate, and the top surface and the side surface of each light-emitting element are covered by the second layer.

4. The packaging structure as claimed in claim 1, wherein the first layer and the plurality of light-emitting elements are separated by the second layer.

5. The packaging structure as claimed in claim 1, wherein the first layer further comprises a first diffusion particle, wherein the first diffusion particle is silicon dioxide, poly(methyl methacrylate), polystyrene, titanium oxide, or a combination thereof.

6. The packaging structure as claimed in claim 5, wherein the first layer further comprises a second diffusion particle, wherein the second diffusion particle is silicon dioxide, poly(methyl methacrylate), polystyrene, titanium oxide, or a combination thereof, and a particle size distribution D90 of the second diffusion particle is less than a particle size distribution D90 of the first diffusion particle.

7. The packaging structure as claimed in claim 1, wherein the second layer further comprises a binder.

8. The packaging structure as claimed in claim 7, wherein the binder comprises aliphatic homopolymer resin, dicyclopentadiene homopolymer resin, aromatic homopolymer resin, or a combination thereof.

9. The packaging structure as claimed in claim 1, wherein adhesion between the composite film and the substrate is 800 gf/25 mm to 2500 gf/25 mm.

10. The packaging structure as claimed in claim 1, wherein the ethylene-propylene copolymer is an ethylene-propylene block copolymer, and a content of a polyethylene block of the ethylene-propylene block copolymer is 7 wt % to 15 wt %, based on a weight of a polypropylene block of the ethylene-propylene copolymer.

11. A method for packaging, comprising:
providing a substrate, wherein a plurality of light-emitting elements are disposed on the substrate; and
providing a composite film and disposing the composite film on the substrate using a thermocompression process to cover the plurality of light-emitting elements, wherein the composite film comprises:
a first layer, wherein the first layer comprises a first thermoplastic material, wherein a melt flow rate of the first thermoplastic material is R1, wherein the first thermoplastic material is an ethylene-propylene copolymer, polyethylene terephthalate, or a combination thereof; and
a second layer, wherein the second layer comprises a second thermoplastic material, wherein a melt flow rate of the second thermoplastic material is R2, and −11≤(R1−R2)≤11, wherein the second thermoplastic material is a styrene-ethylene-butylene-styrene block copolymer, an ethylene-vinyl acetate copolymer, or a combination thereof.

12. The method for packaging as claimed in claim 11, wherein the thermocompression process has a temperature of 130° C. to 150° C.
